(19) United States
(12) Patent Application Publication
(10) Pub. No.: US 2002/0117660 A1
(43) Pub. Date: Aug. 29, 2002

(54) Quantum type phototransistor

(75) Inventor: Hoon Kim, Ulsan City (KR)

Correspondence Address: Brian S. Rosenbloom, Esquire, Mintz levin Cohn Ferris, Glovsky and Popeo PC, 11911 Freedom Drive, Suite 400, Reston, VA, 20190, US

(73) Assignee: Evergreen Korea Corporation, Seoul (KR)

(21) Appl. No.: 09/841,771

(22) Filed: Apr. 25, 2001

(30) Foreign Application Priority Data
Feb. 26, 2001 (KR) 2001-9788

(51) Int. Cl. H01L 29/82; H01L 29/06

(52) U.S. Cl. 257/21; 257/187; 257/198; 257/17

(57) ABSTRACT

By positively employing a quantum structure such as a point contact, a quantum fine line, and a quantum dot on a semiconductor material so that an electric potential barrier is generated from a quantum effect of a conductive region, that is, from the constraint energy of one or zero dimension of electrons or holes and the electric potential barrier is controlled, flow and intensity of an electric current are controlled when light or electromagnetic wave is irradiated. A conductive region is formed by a quantum structure in which a difference in the constraint energies of the holes or electrons is formed between two electrodes, and when the light or electromagnetic wave is irradiated to a partial depletion region of the holes or electrons generated in the quantum structure, pairs of the electrons and the holes are generated in the partial depletion region. Thus, the depletion is released and an electric current flows therein.

### FIELD OF INVENTION

The invention relates to a phototransistor, and more particularly, a quantum type phototransistor in which flow and intensity of an electric current can be controlled, when light or electromagnetic wave is irradiated, by positively employing a quantum structure such as a point contact, a quantum fine line, and a quantum dot on a semiconductor material so that an electric potential barrier is generated from a quantum effect of a conductive region, that is, from the constraint energy of one or zero dimension of electrons or holes and the electric potential barrier is controlled.

### BACKGROUND OF INVENTION

Generally, the phototransistor transforms a light energy or electromagnetic wave energy into an electric energy. When light or electromagnetic wave is irradiated to the phototransistor, electrons or holes are generated by the irradiated light or electromagnetic wave energy and then flow toward an external circuit

At this time, if an inverse voltage has been previously applied to the phototransistor, only a little inverse current flows when the light or the electromagnetic wave is not irradiated.

Further, when the light or the electromagnetic wave is irradiated under the condition that the inverse voltage has been previously applied to the phototransistor, the irradiated light or electromagnetic wave generates the electrons and holes, so that the inverse electric current is increased. Therefore, a certain electric current corresponding to the incident light or electromagnetic wave can be outputted. The outputted current is called a photocurrent.

That is, the phototransistor is a semiconductor device which serves as a photoelectric tube, and it is widely used for phototelegraphy, reproduction of talkies, reading of punching tapes, and so on. Further, since the phototransistor can be made smaller than the photoelectric tube, it is very convenient in such a case that a number of the phototransistors should be used in a narrow space. Since the wavelength sensitivity characteristics extend to a range of infrared ray rather than a range of visual sensitivity, the phototransistor is widely used in the applications including infrared communication, infrared detection, infrared wiretap alarm device, etc.

FIG. 1 is a cross-sectional view for showing a structure of the conventional phototransistor.

As shown in FIG. 1, the conventional phototransistor is formed in a manner that n-type collector layer 11, p-type base layer 12 and n-type emitter layer 13 are sequentially stacked on a semiconductor substrate 10. Electrodes 14 and 15 are formed onto the n-type emitter layer 13 and under the semiconductor substrate 10, respectively.

The p-type base layer 12 is formed to have a structure of multiple quantum wells.

In the conventional phototransistor having the above structure, when electric power is not applied thereto, the conduction band Ec and the valence band Ev of the n-type collector layer 11 and the n-type emitter layer 13 have an energy level lower than the conduction band Ec and the valence band Ev of the p-type base layer 12, as shown in FIG. 2a.

Herein, a well 20 of the p-type base layer 12 proximate to the n-type emitter layer 13 has a band gap smaller than and a width larger than wells 21 of the other portions. The well 20 can be formed such that it has mole concentration higher than that of the wells 21 of the other portions.

Further, when electric power is applied to the n-type emitter layer 13 and the semiconductor substrate 10 via the electrodes 14 and 15, the conduction band Ec and the valence band Ev of the n-type emitter layer 13 are increased in view of the energy level and the conduction band Ec and the valence band Ev of the n-type collector layer 11 are relatively further decreased, as shown in FIG. 2b.

When the light or electromagnetic wave is irradiated in this state, the holes are excited from a bounded state to a continuum state by the irradiated light or electromagnetic wave and move to the n-type emitter layer 13 by the applied electric power. At this time, the holes are easily confined in the well 20 during their movement to the n-type emitter layer 13.

Therefore, a great deal of the holes are collected in the well and a great deal of the electrons move into the well 20 in order to satisfy neutrality, and then the moved electrons move to the n-type collector layer 11. Consequently, the electric current can flow therein.

In the conventional phototransistor, however, the energy level of the conduction band and the valence band of the n-type emitter layer 13 should be increased while the energy level of the conduction band and the valence band of the collector layer should be decreased, in order to promote flow of the electrons. Further, electric power higher than a predetermined energy level should be applied thereto in order to lower the energy level, and thus consumption of the electric power is increased. Therefore, it is not suitable for use in a phototransistor in which a low voltage operation is required.

Furthermore, it is difficult to manufacture the conventional phototransistor mentioned above in that the construction thereof is complicated. It is also difficult to miniaturize the phototransistor in that the size thereof should be increased so as to improve the sensitivity thereof.

### SUMMARY OF INVENTION

It is an object of the present invention to provide a quantum type phototransistor which has a simple structure, a high compaction and a high sensitivity, and which can be driven by a low electric power.

Another object of the present invention is to provide a quantum type phototransistor of which amplification rate is high and of which signal-transmitting speed is fast by allowing a photocurrent to flow in a single carrier.

To accomplish these objects, the present invention provides a quantum type phototransistor, wherein a conductive region is formed by a quantum structure in which a difference in the constraint energies of the holes or electrons is formed between two electrodes, and wherein when the light or electromagnetic wave is irradiated to a partial depletion region of the holes or electrons generated in the quantum structure, pairs of the electrons and the holes are generated in the partial depletion region, and the depletion is released, and thus an electric current flows therein.

### BRIEF DESCRIPTION OF THE DRAWINGS

The objects, features and advantages of the present invention will be apparent to a person skilled in the art from the following detailed description in conjunction with the accompanying drawings, in which:

FIG. 1 is a cross-sectional view showing a structure of a conventional phototransistor;

FIGS. 2a and 2b are views showing energy band structures before and after electric power is applied to the conventional phototransistor, respectively;

FIGS. 3a, 3b, 4a and 4b are views showing an operating principle of the quantum type phototransistor according to the present invention;

FIG. 5 is a view showing a principle of constructing the quantum type phototransistor according to an embodiment of the present invention;

FIG. 6 is a view showing a principle of constructing the quantum type phototransistor according to another embodiment of the present invention;

FIG. 7 is a view showing an example of applying the quantum type phototransistor of the present invention to a SOI structure;

FIGS. 8, 9a and 9b are energy diagrams of the quantum type phototransistor according to the present invention;

FIGS. 10a and 10b are graphs showing measurement results of conductive characteristics of the quantum type phototransistor according to the present invention; and

FIG. 11 is a graph showing a measurement result of sensitivity characteristics of the quantum type phototransistor according to the present invention.

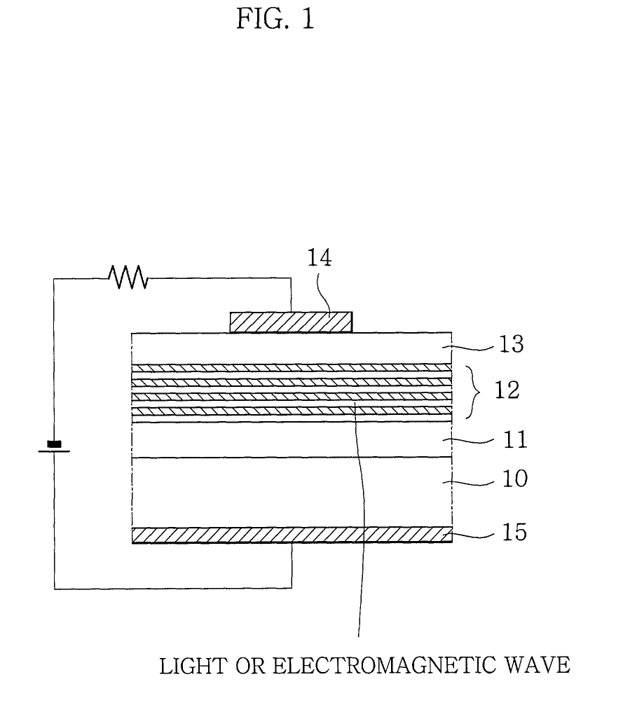

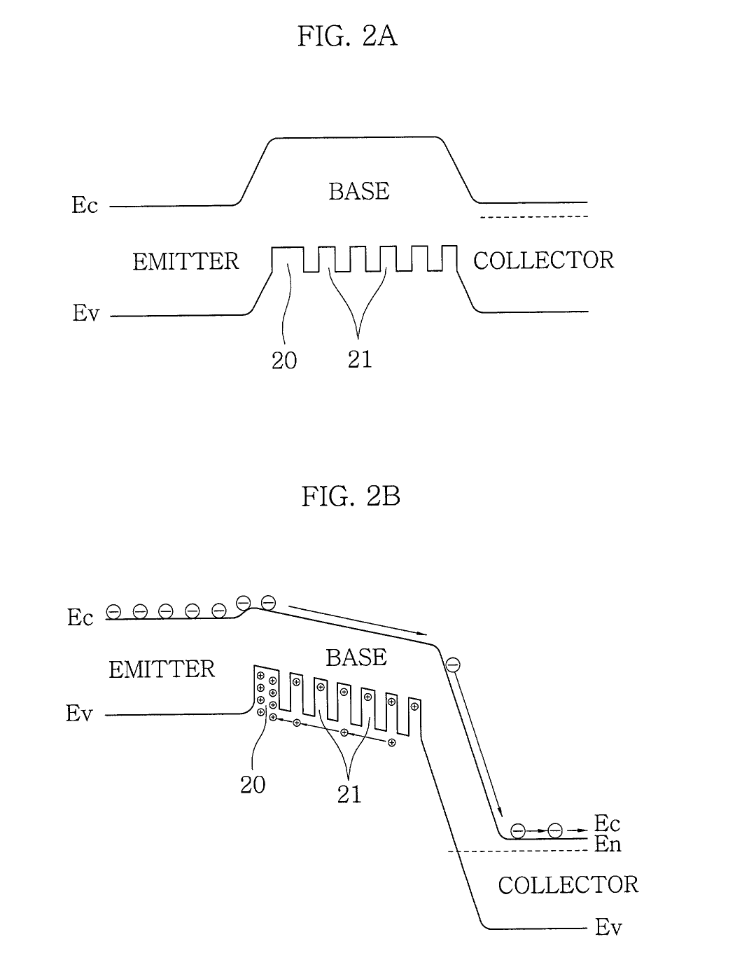

### DETAILED DESCRIPTION OF PREFERRED EMBODIMENT

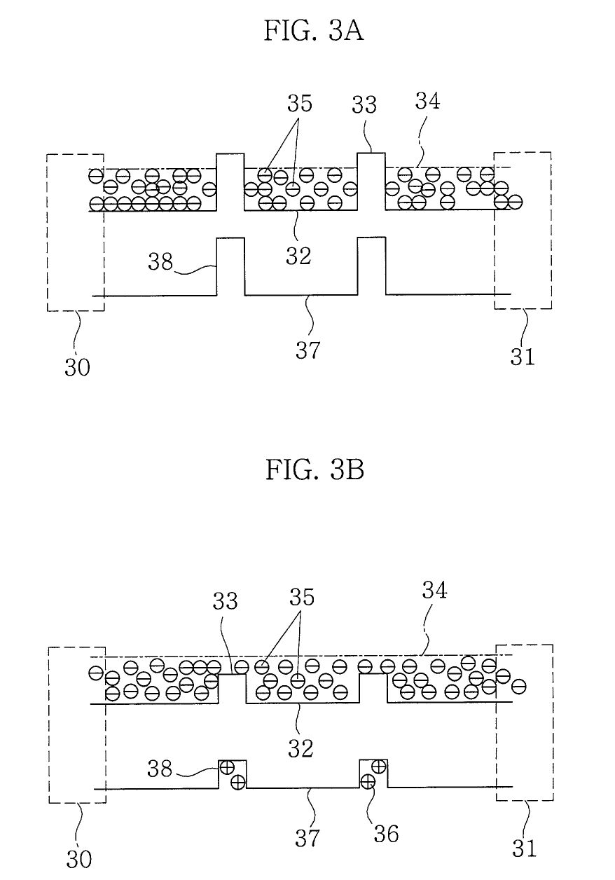

Hereinafter, a quantum type phototransistor according to the present invention will be explained in detailed with reference to FIGS. 3 to 11.

As shown in FIG. 3a, if light or electromagnetic wave is not irradiated under the condition that an electric potential barrier 33 corresponding to a depletion region of a conductive band 32 between a source electrode 30 and a drain electrode 31 is set higher than a Fermi energy level 34, flow of electrons 35 is controlled or prevented by the electric potential barrier 33.

As shown in FIG. 3b, if the light or electromagnetic wave is irradiated, holes 36 generated by the light or electromagnetic wave are accumulated in a partial depletion region of a valence band 37, and a height of the electric potential barrier 33 is relatively lowered by the accumulated holes 36. Thus, the electrons flow between the source electrode 30 and the drain electrode 31.

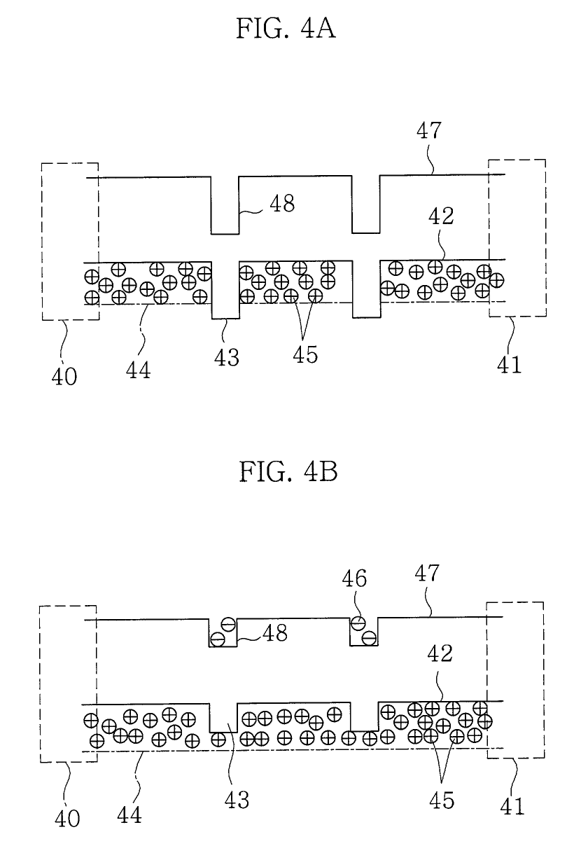

Similarly, as shown in FIG. 4a, if when light or electromagnetic wave is not irradiated under the condition that an electric potential barrier 43 corresponding to a depletion region of a valence band 42 between a source electrode 40 and a drain electrode 41 is set higher than a Fermi energy level 44, flow of the holes 45 is controlled or prevented by the electric potential barrier 43.

As shown in FIG. 4b, if the light or electromagnetic wave is irradiated, electrons 46 generated by the light or electromagnetic wave are accumulated in a partial depletion region 48 of a conduction band 47, and a height of the electric potential barrier 43 is relatively lowered by the accumulated electrons. Thus, the holes 45 flow between the source electrode 40 and the drain electrode 41.

Therefore, the flow of the electrons 35 and the holes 45 become an electric current generated by the irradiated light and electromagnetic wave, which is, in turn, used for transmitting a signal.

That is, when the light or electromagnetic wave is irradiated, a large electric current can flow although the number of the holes accumulated in the partial depletion region 38 of the valence band 37 is small, and a large electric current can also flow although the number of the electrons accumulated in the partial depletion region 48 of the conduction band 47 is small. Therefore, the holes and the electrons can pass over the electric potential barrier 33 and 43 formed by the quantum effect and can be transmitted as the electrical signal, even if a faint light or electromagnetic wave is irradiated.

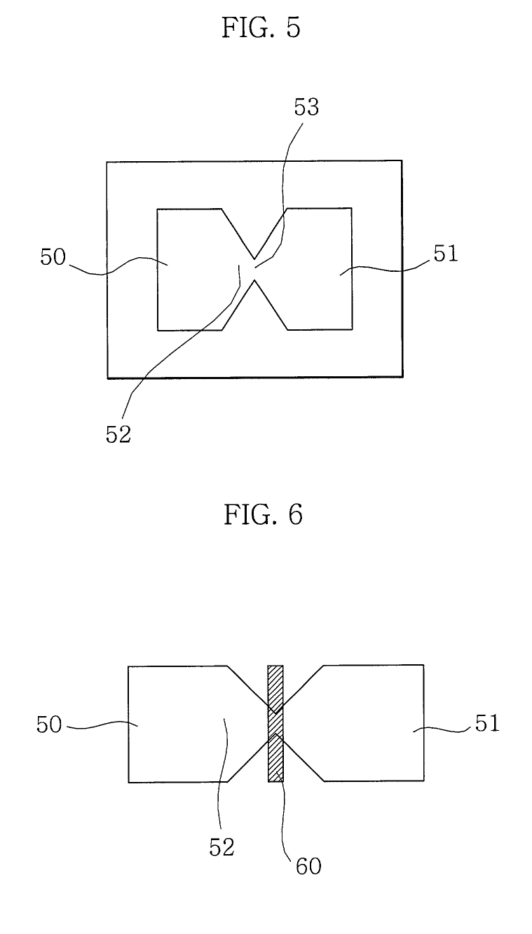

As shown in FIG. 5, in the quantum type phototransistor using the principle mentioned above, a transit part 53 having a bottleneck structure of a quantum size less than hundreds of nm in width is formed at a portion of a conductive region 52 between a source 50 and a drain 51.

In the transit part 53 having the bottleneck structure according to the present invention, a depletion phenomenon of conductive carriers can be occurred in the transit part 53 of bottleneck structure by the quantum size effect, which is identical with a surface depletion phenomenon appearing in the semiconductor material, when the light or electromagnetic wave is irradiated.

Therefore, when the light or electromagnetic wave is not irradiated or an adequate voltage is not applied between the source 50 and the drain 51, a signal as an electric current due to flow of the electrons or holes cannot be transmitted through the electric potential barrier of the conduction band or the valence band.

Further, since the electric potential barrier of the conduction band or the valence band is lowered when the light or electromagnetic wave is irradiated, the electrons and the holes can pass through the transit part 53 and the electric current can flow therein.

In addition, the above-mentioned principle of the present invention can be simply embodied in various forms. As shown in FIG. 6, the Fermi energy level in a portion of a depletion-inducing substance 60 can be increased by adding the depletion-inducing substance 60 of a nano-size width to a portion of the conductive region 52, and thus the same effect as in the transit part 53 having the bottleneck structure can be obtained.

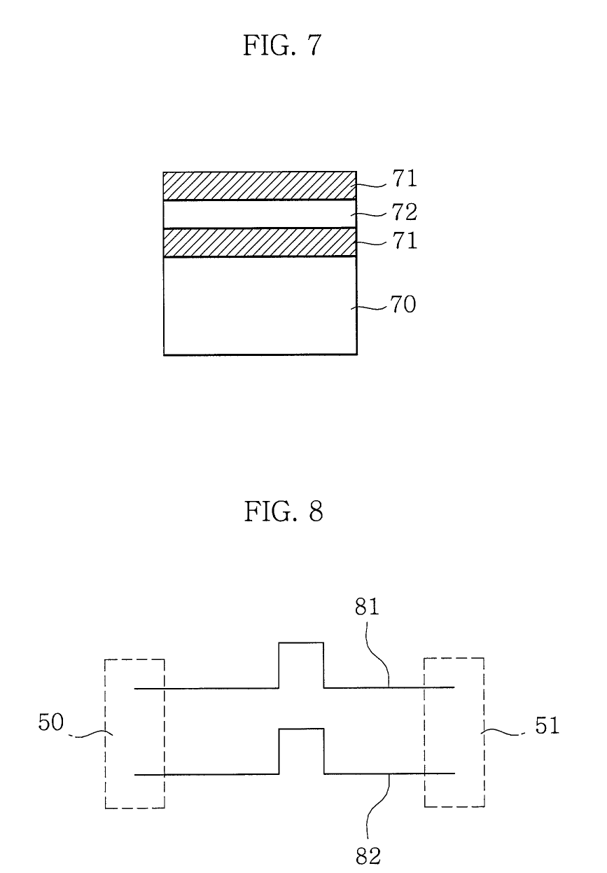

In the present invention, the conductive region 72 quantized on the semiconductor surface can be formed directly on a bulk type semiconductor; or as shown in FIGS. 5 and 6, it can be formed by physically and chemically etching a silicon film 70 in SOI (Silicon On Insulator) structure in which silicon oxide film 71 and a thin silicon film 72 are sequentially deposited onto the silicon substrate 70 as shown in FIG. 7. Thereafter, the Fermi level of the electrons or holes is increased by the ion implantation into the conductive region, and thus the current can always flow therein.

At this time, in order to form the partial depletion region, ion implantation into the transit part 53 having the bottleneck structure or into the depletion inducing substance 60 should not be made, so that the Fermi level of the electron or the hole becomes lower than the energy level of the partial depletion region. That is, the partial insulating region is formed at a portion of the conductive region 72 by making a low dimensional structure of the conductive electron and hole layer for generating the quantum effect of the conductive electrons, and thus an inside of the electron and the hole layer may be partially depleted under the influence of the partial insulating region.

In the present invention, a plurality of the phototransistors can be installed on the single bulk type semiconductor or the SOI substrate, and can also be connected with one another in series, in parallel and in the form of matrix. Thus, the phototransistors can be used for increasing the output current or as an image sensor, etc.

FIG. 8 shows an energy band diagram of the structure formed by the above-mentioned process. In FIG. 8, the meaning of physical properties forming the conductive carrier into the transit part 53 having the bottleneck structure is illustrated, as an example of the silicon substrate.

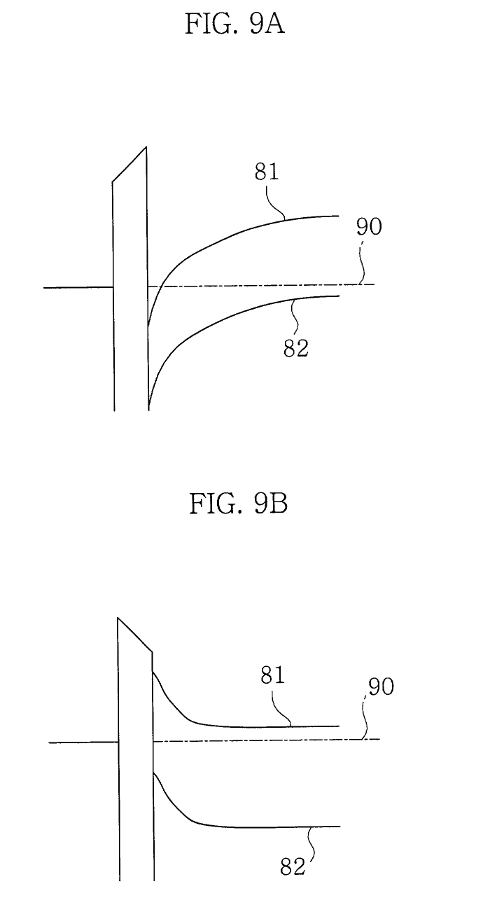

As shown in FIG. 9a, the energy band diagram of a region between the source 50 and the drain 51, in which ions are doped with a high concentration thereof, indicates that the Fermi energy level 90 of the conductive electron is raised and thus the conduction band 81 can be always filled with free electrons. On the other hand, since the conductive region remained by the etching process in the transit part 53 with the bottleneck structure is formed to be less than hundreds of nm thick, the electric potential barrier identical to a pinning phenomenon of the Fermi energy level 90 on the semiconductor surface is generated. As shown in FIG. 9b, the conduction band 81 and the valence band 82 are raised between the silicon layer and the silicon oxide film like the phenomenon occurred in MOSFET. Thus, the conductive electrons become depleted.

The phototransistor of the present invention has a very simple construction. Further, it is possible to enable a large electric current to flow even by a small quantity of the electrons and holes by depleting beforehand a great deal of the conductive electrons and holes due to the quantum effect. Thus, the phototransistor has the function of high sensitivity and high amplification.

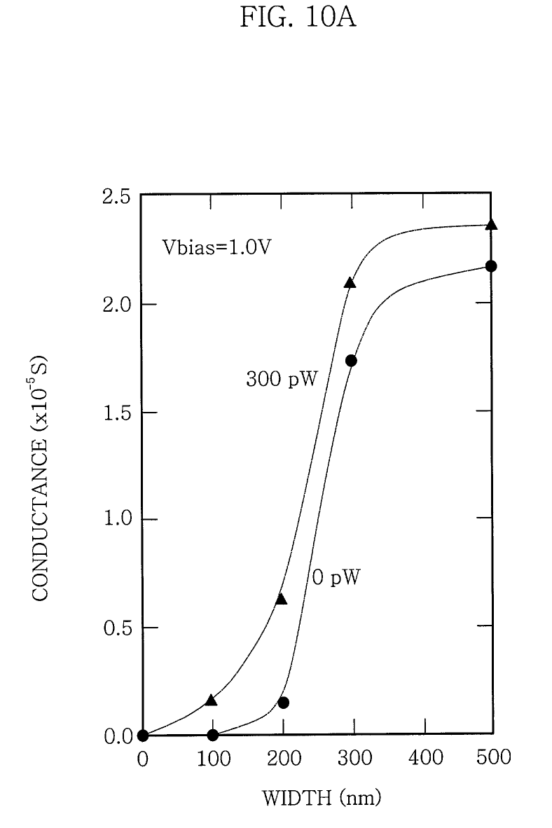

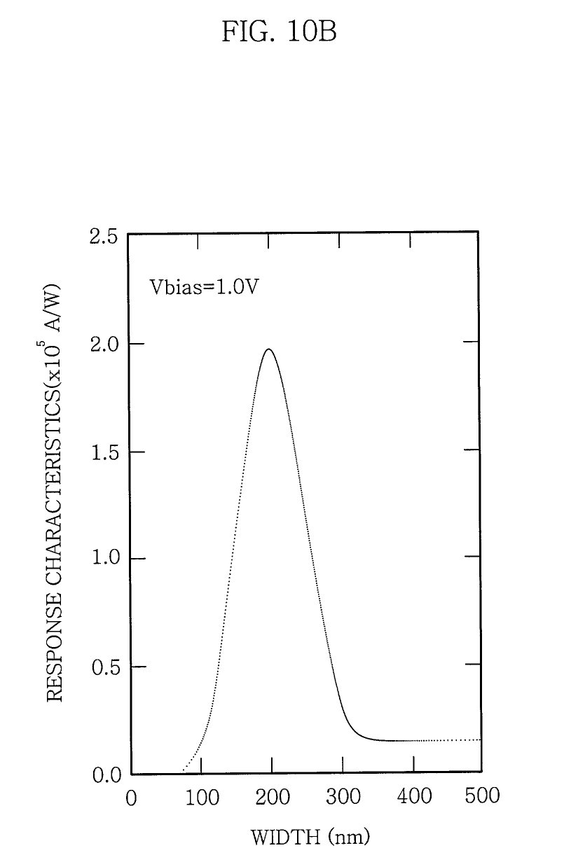

Photoconductive characteristics of the phototransistor according to the present invention have been measure and the results have been obtained as shown in FIGS. 10a and 10b.

In these figures, the conductive characteristics between the source 50 and the drain 51, that is, relationships between an intensity of light and a width variation of the transit part having the bottleneck structure when a proper voltage is applied therebetween, are shown.

As seen from FIG. 10a, the wider the conductive region is, the larger the conductance between the source 50 and the drain 51. However, the phototransistor cannot work, in a case where the conductive region becomes too wide, where the transit part with the bottleneck structure made by using the quantum effect is not formed therein, or where the conductive electron layer is cut off in the insulating structure.

Referring particularly to FIG. 10b, the response characteristics are most preferable when the transit part with the bottleneck structure has a width of 200 nm. However, the response characteristics may be varied depending on the material properties and the kinds of the conductive carriers.

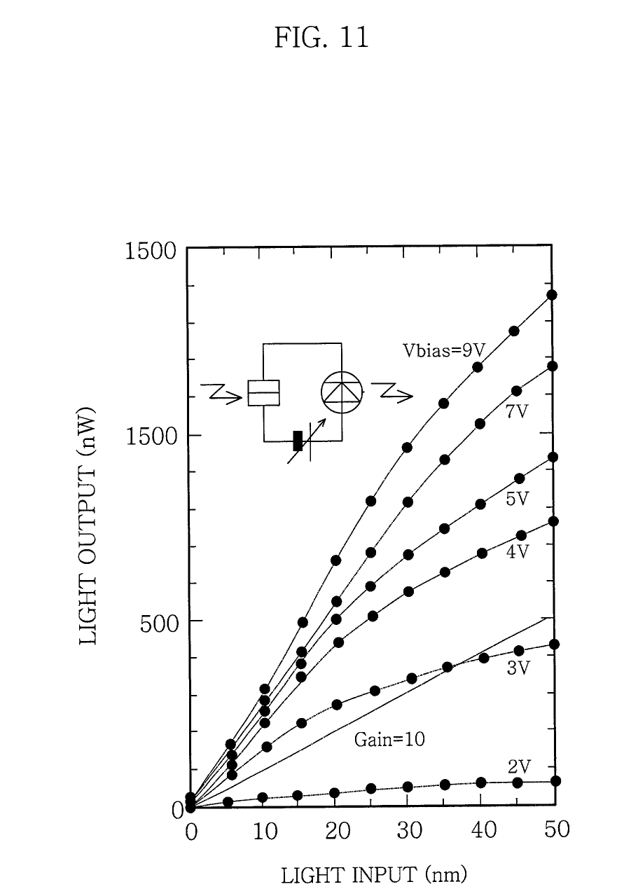

Further, as shown in FIG. 11, the stronger the intensity of the light and electromagnetic wave is, the larger the electric current is. It is understood from the gradient of the intensity and the current that the quantum type phototransistor having a high sensitivity more than a hundred thousand A/W or a high amplification more than a hundred thousand times can be realized.

Although the present invention has been illustrated and described with reference to the preferred embodiments, it is apparent to a person having an ordinary knowledge in the art that any changes or modifications may be made without departing from the scope and spirit of the invention defined in the claims attached hereto.

For example, in the phototransistor of the present invention, only the electrons or holes are used as conductive elements when converting the optical signal into the electric signal. Further, the phototransistor of the present invention has such a structure that the electric potential barrier, resulting from the quantum effect, of the transit portion having the bottleneck structure can be lowered by only several electrons or holes. Therefore, high sensitivity can be obtained and nano-size elements are highly integrated simultaneously by a batch process. Although the depletion region of the conductive electron layer is formed on a surface in FIG. 5, it is also possible to three dimensionally manufacture a structure that is symmetrical up and down. The partial insulating region of the conductive electron layer by the quantum effect does not have to be located in a center thereof, and may be situated at a point leaned to the edge. Further, the partial insulating region by the quantum effect does not have to be formed by the chemical etching, and may be formed by an electric depletion using a metal electrode. Since a small distance between the partial insulating region and the source or the drain allows the overall resistance to be reduced, the electric current becomes larger. Moreover, the partial electric potential barrier can be formed by depositing materials having high dielectric constants onto the silicon substrate.

FIGS. 5, 6 and 7 show examples for forming the thin film type silicon structure on the insulator using the silicon semiconductor. The objective mentioned above can be achieved by forming a modulating doped quantum well or hetero junction structure of III-V group semiconductor. Further, metal, germanium, bulk-type silicon substrate, or other material if it has a conductivity corresponding to the light or electromagnetic wave, may be used. The objective mentioned above can also be achieved by manufacturing a vertical type structure instead of the surface type structure shown in FIG. 5. Therefore, easy stacking with the other elements can be made.

As described above, since the quantum type phototransistor according to the present invention has a simple structure and a high sensitivity to the light or electromagnetic wave, it can also be used as a photodetector or photosensor. Further, the quantum type phototransistor according to the present invention having high performance can replace the conventional phototransistor or can be used as an element having new functions.

Further, since a plurality of the quantum type phototransistors according to the present invention can be simply connected, they have an enhanced output and can be used as one or two dimensional image sensors by forming an amplification circuit on the same chip through a batch process. Furthermore, since the output current is large, a light-emitting device such as a light-emitting diode may be directly driven by a power source attached thereto.

At this time, since the light output is greater than the light input, the quantum type phototransistor can be used as a noctovisonal camera and applied to an optical memory such as a light amplifier for use in analog or digital optical circuits.

The phototransistor responsive to the light or electromagnetic wave having an arbitrary wavelength and the phototransistor having an arbitrary amplification rate can be constructed by arbitrary controlling the depletion energy level of the conductive electron by the quantum effect.

What is claimed is:

1. A quantum type phototransistor, comprising:
two electrodes formed on both sides of a semiconductor substrate to output a photocurrent;
a conductive region provided between said two electrodes of said semiconductor substrate, through which holes and electrons are moved; and
a transit part having a bottleneck structure formed in said conductive region, and said transit part being provided with a partial electric potential barrier for cutting off flow of said electrons or said holes and allowing said electrons or said holes to flow by releasing said electric potential barrier when light or electromagnetic wave is irradiated thereto.

2. The quantum type phototransistor as claimed in claim 1, further comprising a plurality of said partial electric potential barriers.

3. The quantum type phototransistor as claimed in claim 1 or 2, wherein said partial electric potential barrier is formed in a conduction band and constructed so that said photocurrent formed by said flow of the electrons by means of the holes therethrough.

4. The quantum type phototransistor as claimed in claim 1 or 2, wherein said partial electric potential barrier is formed in a valence band and constructed so that said photocurrent formed by said flow of the holes by means of the electrons therethrough.

5. The quantum type phototransistor as claimed in claim 1, wherein said transit part having the bottleneck structure is formed by a quantum line.

6. The quantum type phototransistor as claimed in claim 1, wherein said transit part having the bottleneck structure is formed by a quantum dot.

7. The quantum type phototransistor as claimed in claim 1, wherein said conductive region is formed on a bulk silicon substrate.

8. The quantum type phototransistor as claimed in claim 1, wherein said conductive region is formed by a metal material, and a partial depletion region of said partial electric potential barrier is formed by an insulating material.

9. The quantum type phototransistor as claimed in claim 1, wherein said substrate is formed to have a modulating doped quantum well or hetero junction structure using III-V group semiconductor.

10. The quantum type phototransistor as claimed in claim 1, wherein said substrate is a silicon substrate having a MOS structure.

11. The quantum type phototransistor as claimed in claim 1, wherein said substrate is a silicon substrate with a metal thin film and oxide film formed thereon.

12. The quantum type phototransistor as claimed in claim 1, wherein said substrate is a SOI substrate.

13. The quantum type phototransistor as claimed in claim 1, wherein said partial electric potential barrier is formed by a material having a high dielectric constant on said silicon substrate.
